(19) United States
(12) Patent Application Publication
(10) Pub. No.: US 2026/0157162 A1
(43) Pub. Date: Jun. 4, 2026

(54) SEMICONDUCTOR CHIP AND SEMICONDUCTOR PACKAGE INCLUDING THE SAME

(71) Applicant: Samsung Electronics Co., Ltd., Suwon-si (KR)

(72) Inventors: Enbin Jo, Suwon-si (KR); Minki Kim, Suwon-si (KR); Won Il Lee, Suwon-si (KR)

(21) Appl. No.: 19/238,002

(22) Filed: Jun. 13, 2025

(30) Foreign Application Priority Data
Dec. 2, 2024 (KR) 10-2024-0176780

(51) Int. Cl. H01L 23/00; H01L 23/48

(52) U.S. Cl. CPC H10W 20/20; H10W 72/9445; H10W 72/967; H10W 72/981; H10W 90/792

(57) ABSTRACT

A semiconductor package includes a semiconductor chip. The semiconductor chip includes a semiconductor substrate having a first surface and a second surface opposed to each other, an integrated circuit layer on the first surface of the semiconductor substrate, a wiring layer on the integrated circuit layer, a first pad and a second pad horizontally spaced apart from each other on the wiring layer and electrically connected to the wiring layer, a first bonding pad on the first pad and electrically connected to the first pad, a buried insulating pattern on the second pad, and a second bonding pad on the buried insulating pattern. The second bonding pad is electrically isolated from the second pad by the buried insulating pattern.

### CROSS-REFERENCE TO RELATED APPLICATION(S)

This U.S. non-provisional patent application claims priority under 35 U.S.C. § 119 of Korean Patent Application No. 10-2024-0176780, filed on Dec. 2, 2024, the entire contents of which are hereby incorporated by reference.

### BACKGROUND

An integrated circuit chip is packaged into a semiconductor package having a suitable form for an electronic device. In general, in a semiconductor package, a semiconductor chip is mounted on a printed circuit board (PCB), and the semiconductor chip and the PCB are electrically connected to each other using bonding wires or bumps. With the development of electronics industry, smaller size, less weight, and multi-functionality of an electronic device are demanded, and accordingly, a multi-chip package in which a plurality of semiconductor chips are stacked in one semiconductor package, a system-in package in which semiconductor chips of different kinds are mounted in one semiconductor package to operate as one system, or the like is being suggested.

In one semiconductor package, a plurality of semiconductor chips may be electrically connected to each other by using a connection member such as bumps or solders or by direct-bonding of chip pads. Various researches are being carried out to improve reliability of interconnection between a plurality of semiconductor chips.

### SUMMARY

The present disclosure relates to a semiconductor chip and a semiconductor package including the same, and more particularly, to a semiconductor package in which a plurality of semiconductor chips are mounted.

The present disclosure provides a semiconductor chip having a structure which facilitates interconnection between a plurality of semiconductor chips.

The present disclosure also provides a semiconductor package which facilitates interconnection between a plurality of semiconductor chips and has excellent reliability.

some implementations provides a semiconductor package including a semiconductor chip, wherein the semiconductor chip includes a semiconductor substrate having a first surface and a second surface opposed to each other, an integrated circuit layer on the first surface of the semiconductor substrate, a wiring layer on the integrated circuit layer, a first pad and a second pad horizontally spaced apart from each other on the wiring layer and electrically connected to the wiring layer, a first bonding pad disposed on the first pad and electrically connected to the first pad, a buried insulating pattern on the second pad, and a second bonding pad on the buried insulating pattern, and the second bonding pad is electrically isolated from the second pad by the buried insulating pattern.

In some implementations, a semiconductor package includes a first semiconductor chip and a second semiconductor chip on the first semiconductor chip, wherein each of the first and second semiconductor chips includes a semiconductor substrate having a first surface and a second surface opposed to each other, a wiring layer on the first surface of the semiconductor substrate, a first pad and a second pad horizontally spaced apart from each other on the wiring layer and electrically connected to the wiring layer, a first bonding pad disposed on the first pad and electrically connected to the first pad, a second bonding pad disposed on the second pad and electrically isolated from the second pad, a first back side bonding pad and a second back side bonding pad disposed on the second surface of the semiconductor substrate and horizontally spaced apart from each other, and a penetration electrode penetrating the semiconductor substrate and electrically connected to the first back side bonding pad, the second back side bonding pad is electrically isolated from the penetration electrode, the first back side bonding pad of the first semiconductor chip is directly bonded to the first bonding pad of the second semiconductor chip, and the second back side bonding pad of the first semiconductor chip is directly bonded to the second bonding pad of the second semiconductor chip.

In some implementations, a semiconductor package includes a semiconductor chip, wherein the semiconductor chip includes a semiconductor substrate having a first surface and a second surface opposed to each other, a wiring layer on the first surface of the semiconductor substrate, a first pad and a second pad horizontally spaced apart from each other on the wiring layer and electrically connected to the wiring layer, a planarized insulating layer disposed on the wiring layer and covering the first pad and the second pad, a bonding insulating layer on the planarized insulating layer, a first bonding pad penetrating the bonding insulating layer and the planarized insulating layer and connected to the first pad, and a second bonding pad penetrating the bonding insulating layer, and the second bonding pad is vertically spaced apart from the second pad and electrically isolated from the second pad.

### BRIEF DESCRIPTION OF THE DRAWINGS

The accompanying drawings are included to provide a further understanding, and are incorporated in and constitute a part of this specification. The drawings illustrate implementations and, together with the description, serve to explain principles. In the drawings:

FIG. 1 is a plan view of a semiconductor chip according to some implementations;

FIG. 2 is a cross-sectional view taken along A-A′ of FIG. 1;

FIGS. 3, 4, 5, 6, 7, and 8 are diagrams, which are cross-sectional views taken along A-A′ of FIG. 1, illustrating a method for manufacturing a semiconductor chip according to some implementations; and

FIGS. 9, 10, 11, and 12 are cross-sectional views of semiconductor packages according to some implementations.

### DETAILED DESCRIPTION

Hereinafter, implementations will be described with reference to the accompanying drawings to describe the details.

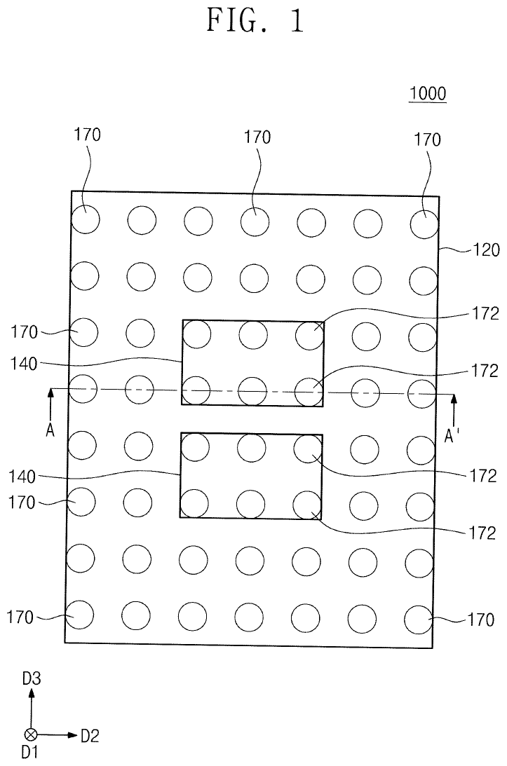

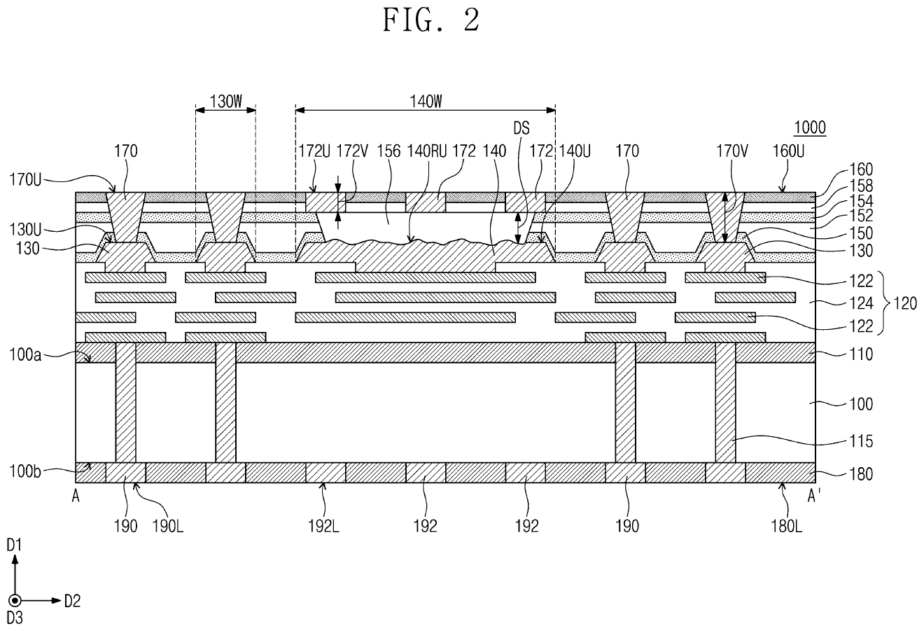

FIG. 1 is a plan view of a semiconductor chip according to some implementations, and FIG. 2 is a cross-sectional view taken along A-A′ of FIG. 1.

Referring to FIGS. 1 and 2, a semiconductor chip 1000 may include a semiconductor substrate 100 having a first surface 100a and a second surface 100b opposed to each other, an integrated circuit layer 110 on the first surface 100a of the semiconductor substrate 100, and a wiring layer 120 on the integrated circuit layer 110. The integrated circuit layer 110 may be disposed between the first surface 100a of the semiconductor substrate 100 and the wiring layer 120. The semiconductor substrate 100 may be a silicon substrate, a germanium substrate, and/or a silicon-germanium substrate. The integrated circuit layer 110 may include integrated circuits which are formed on the semiconductor substrate 100, and may include, for example, a logic circuit and/or a memory circuit.

The wiring layer 120 may include a plurality of wiring patterns 122 spaced apart from each other in a first direction D1 perpendicular to the first surface 100a of the semiconductor substrate 100 and a wiring insulating layer 124 disposed on the first surface 100a of the semiconductor substrate 100 and covering the plurality of wiring patterns 122. The plurality of wiring patterns 122 may be electrically connected to the integrated circuit layer 110. The plurality of wiring patterns 122 may include a conductive material, and for example, may include metal such as copper, aluminum, titanium, or tungsten, and/or conductive metal nitride. The wiring insulating layer 124 may include an insulating material, and for example, include silicon oxide, silicon nitride, silicon oxynitride, and/or tetraethyl orthosilicate (TEOS).

The semiconductor chip 1000 may include a first pad 130 and a second pad 140 disposed on the wiring layer 120 and horizontally spaced apart from each other. The first pad 130 may be provided in plurality, and the plurality of first pads 130 may be horizontally spaced apart from each other on the wiring layer 120. For example, the plurality of first pads 130 may be spaced apart from each other along a second direction D2 and a third direction D3 parallel to the first surface 100a of the semiconductor substrate 100 and intersecting each other. The second pad 140 may be provided in plurality, and the plurality of second pads 140 may be horizontally spaced apart from each other on the wiring layer 120. For example, the plurality of second pads 140 may be spaced apart from each other in the third direction D3. Each of the plurality of second pads 140 may be disposed between a pair of first pads 130, among the plurality of first pads 130, spaced apart from each other in the second direction D2.

The first pad 130 and the second pad 140 may be electrically connected to the wiring layer 120. The first pad 130 and the second pad 140 may be electrically connected to the plurality of wiring patterns 122. A portion of the first pad 130 may extend into the wiring insulating layer 124 and may be electrically connected to a corresponding wiring pattern 122 among the plurality of wiring patterns 122. A portion of the second pad 140 may extend into the wiring insulating layer 124 and may be electrically connected to a corresponding wiring pattern 122 among the plurality of wiring patterns 122.

Each of the first pad 130 and the second pad 140 may have a maximum width along a direction (for example, the second direction D2 or the third direction D3) parallel to the first surface 100a of the semiconductor substrate 100. A maximum width 140W of the second pad 140 may be greater than a maximum width 130W of the first pad 130. An upper surface 140U of the second pad 140 may include at least one recessed surface 140RU which is recessed toward an inside of the second pad 140. The first pad 130 may be electrically connected to the integrated circuit layer 110 through corresponding wiring patterns 122 among the plurality of wiring patterns 122. The second pad 140 may be electrically connected to test patterns for testing electrical characteristics of the semiconductor chip 1000 through corresponding wiring patterns 122 among the plurality of wiring patterns 122. The second pad 140 may be referred to as a test pad. The first pad 130 and the second pad 140 may include a conductive material, and for example, may include at least one of aluminum, tungsten, or copper.

The semiconductor chip 1000 may include a planarized insulating layer 152 disposed on the wiring layer 120 and covering the first pad 130 and the second pad 140. The planarized insulating layer 152 may include an insulating material, and for example, include silicon oxide, silicon nitride, silicon oxynitride, and/or tetraethyl orthosilicate (TEOS). The semiconductor chip 1000 may further include a capping insulating layer 150 interposed between the planarized insulating layer 152 and each of the first and second pads 130 and 140. The capping insulating layer 150 may conformally cover the first and second pads 130 and 140 and extend between the wiring insulating layer 124 and the planarized insulating layer 152. The capping insulating layer 150 may include an insulating material, and for example, include silicon oxide, silicon nitride, and/or silicon oxynitride.

The semiconductor chip 1000 may further include a first insulating layer 154 disposed on the planarized insulating layer 152. The first insulating layer 154 may include an insulating material, and for example, include silicon oxide, silicon nitride, and/or silicon oxynitride. According to some implementations, the first insulating layer 154 may include a material different from that of the planarized insulating layer 152. For example, the planarized insulating layer 152 may include silicon oxide, and the first insulating layer 154 may include silicon nitride.

The semiconductor chip 1000 may further include a buried insulating pattern 156 disposed on the upper surface 140U of the second pad 140. The buried insulating pattern 156 may extend through the first insulating layer 154, the planarized insulating layer 152, and the capping insulating layer 150 and cover the upper surface 140U of the second pad 140. The buried insulating pattern 156 may be in contact with the upper surface 140U of the second pad 140. The buried insulating pattern 156 may include an insulating material, and for example, include silicon oxide, silicon nitride, and/or silicon oxynitride. The buried insulating pattern 156 may be provided in plurality, and the plurality of buried insulating patterns 156 may be respectively disposed on the plurality of second pads 140. For example, the plurality of buried insulating patterns 156 may be spaced apart from each other in the third direction D3.

The semiconductor chip 1000 may further include a second insulating layer 158 disposed on the first insulating layer 154 and covering an upper surface of the buried insulating pattern 156 and a bonding insulating layer 160 on the second insulating layer 158. The second insulating layer 158 may include an insulating material, and for example, include silicon oxide, silicon nitride, silicon oxynitride, and/or tetraethyl orthosilicate (TEOS). The bonding insulating layer 160 may include an insulating material, and for example, include silicon oxide, silicon nitride, and/or silicon oxynitride. According to some implementations, the bonding insulating layer 160 may include a material different from that of the second insulating layer 158. For example, the second insulating layer 158 may include silicon oxide, and the bonding insulating layer 160 may include silicon nitride.

The semiconductor chip 1000 may further include a first bonding pad 170 disposed on the first pad 130 and electrically connected to the first pad 130 and a second bonding pad 172 on the buried insulating pattern 156. The first bonding pad 170 may extend through the bonding insulating layer 160, the first and second insulating layers 154 and 158, the planarized insulating layer 152, and the capping insulating layer 150 and may be electrically connected to the first pad 130. The first bonding pad 170 may be in contact with an upper surface 130U of the first pad 130. The second bonding pad 172 may extend through the bonding insulating layer 160 and the second insulating layer 158 and may be disposed on the buried insulating pattern 156. The second bonding pad 172 may be vertically (for example, in the first direction D1) spaced apart from the second pad 140 and may be electrically isolated from the second pad 140 by the buried insulating pattern 156. The second bonding pad 172 may be an electrically floating dummy pad.

The first bonding pad 170 may be provided in plurality, and the plurality of first bonding pads 170 may be respectively disposed on the plurality of first pads 130. For example, the plurality of first bonding pads 170 may be spaced apart from each other along the second direction D2 and the third direction D3. The second bonding pad 172 may be provided in plurality, and the plurality of second bonding pads 172 may be disposed on each buried insulating pattern 156. For example, the plurality of second bonding pads 172 may be spaced apart from each other along the second direction D2 and the third direction D3 on each buried insulating pattern 156. A pattern density of the plurality of second bonding pads 172 may be substantially the same as a pattern density of the plurality of first bonding pads 170. Here, the wording “substantially the same” includes an error range of about +10% to about −10%.

The bonding insulating layer 160 may expose an upper surface 170U of the first bonding pad 170 and an upper surface 172U of the second bonding pad 172. An upper surface 160U of the bonding insulating layer 160, the upper surface 170U of the first bonding pad 170, and the upper surface 172U of the second bonding pad 172 may constitute one surface and may be located at substantially the same height from the first surface 100a of the semiconductor substrate 100. Here, the height is a distance which is measured in the first direction D1 from the first surface 100a.

Each of the first bonding pad 170 and the second bonding pad 172 may have a vertical length along a direction (for example, the first direction D1) perpendicular to the first surface 100a of the semiconductor substrate 100. A vertical length 170V of the first bonding pad 170 may be greater than a vertical length 172V of the second bonding pad 172.

The first bonding pad 170 and the second bonding pad 172 may include a conductive material, and for example, may include metal. The first bonding pad 170 and the second bonding pad 172 may include, for example, at least one of aluminum, tungsten, or copper. The first bonding pad 170 and the second bonding pad 172 may include the same metal, and for example, may include copper.

The second bonding pad 172 may be spaced apart from the second pad 140 by a first distance DS in the first direction D1. The first distance may be measured from the upper surface 140U (or the recessed surface 140RU) of the second pad 140 to a bottom surface of the second bonding pad 172 in the first direction D1. The first distance DS may be, for example, about 1.6 μm to about 3.6 μm. In a case in which the first distance DS is smaller than about 1.6 μm, it may be difficult to form the second bonding pad 172 so as to be electrically isolated from the second pad 140.

The semiconductor chip 1000 may further include a first back side bonding pad 190 and a second back side bonding pad 192 disposed on the second surface 100b of the semiconductor substrate 100 and horizontally spaced apart from each other, a penetration electrode 115 extending through the semiconductor substrate 100 and electrically connected to the first back side bonding pad 190, and a back side bonding insulating layer 180 disposed on the second surface 100b of the semiconductor substrate 100 and covering side surfaces of the first back side bonding pad 190 and the second back side bonding pad 192.

The first back side bonding pad 190 may be electrically connected to the wiring layer 120 and the integrated circuit layer 110 through the penetration electrode 115. The second back side bonding pad 192 may not be connected to the penetration electrode 115, and may be electrically isolated from the penetration electrode 115, the wiring layer 120, and the integrated circuit layer 110. The second back side bonding pad 192 may be an electrically floating back side dummy pad.

The back side bonding insulating layer 180 may expose a lower surface 190L of the first back side bonding pad 190 and a lower surface 192L of the second back side bonding pad 192. A lower surface 180L of the back side bonding insulating layer 180, the lower surface 190L of the first back side bonding pad 190, and the lower surface 192L of the second back side bonding pad 192 may constitute one surface and may be located at substantially the same height from the second surface 100b of the semiconductor substrate 100. Here, the height is a distance which is measured in the first direction D1 from the second surface 100b.

The first back side bonding pad 190 and the second back side bonding pad 192 may include a conductive material, and for example, may include metal. The first back side bonding pad 190 and the second back side bonding pad 192 may include, for example, at least one of aluminum, tungsten, or copper. The first back side bonding pad 190 and the second back side bonding pad 192 may include the same metal, and for example, may include copper. The first bonding pad 170, the second bonding pad 172, the first back side bonding pad 190, and the second back side bonding pad 192 may include the same metal, and for example, may include copper.

The penetration electrode 115 may include a conductive material, and for example, include metal (for example, copper (Cu)). The back side bonding insulating layer 180 may include an insulating material, and for example, include silicon oxide, silicon nitride, and/or silicon oxynitride.

In a case in which the second bonding pad 172 is not provided in a region vertically overlapping the second pad 140 having a relatively great width, a defect such as dishing or erosion may occur during a planarization process for forming the first bonding pad 170, and accordingly, upper surfaces of the first bonding pad 170 and the bonding insulating layer 160 may have non-uniform distribution of height. Likewise, in a case in which the second back side bonding pad 192 is not provided in a region vertically overlapping the second pad 140 having a relatively great width, a defect such as dishing or erosion may occur during a planarization process for forming the first back side bonding pad 190, and accordingly, upper surfaces of the first back side bonding pad 190 and the back side bonding insulating layer 180 may have non-uniform distribution of height. In this case, when a plurality of semiconductor chips 1000 are stacked in a vertical direction (for example, the first direction D1) and connected to each other using a direct-bonding (for example, hybrid copper bonding (HCB)) method, a defect such as a void may occur between the plurality of semiconductor chips 1000, and as a result, it may be difficult to connect the plurality of semiconductor chips 1000 to each other using a direct-bonding (for example, hybrid copper bonding (HCB)) method.

According to some implementations, since the second bonding pad 172 is disposed in a region vertically overlapping the second pad 140 having a relatively great width, a pattern density of the first and second bonding pads 170 and 172 may be uniform. Accordingly, occurrence of a defect such as dishing or erosion may be minimized during a planarization process for forming the first and second bonding pads 170 and 172, and as a result, the upper surfaces 170U, 172U, and 160U of the first and second bonding pads 170 and 172 and the bonding insulating layer 160 may have uniform distribution of height. Likewise, since the second back side bonding pad 192 is disposed in a region vertically overlapping the second pad 140 having a relatively great width, a pattern density of the first and second back side bonding pads 190 and 192 may be uniform. Accordingly, occurrence of a defect such as dishing or erosion may be minimized during a planarization process for forming the first and second back side bonding pads 190 and 192, and as a result, the lower surfaces 190L, 192L, and 180L of the first and second back side bonding pads 190 and 192 and the back side bonding insulating layer 180 may have uniform distribution of height. Thus, the plurality of semiconductor chips 1000 stacked in a vertical direction (for example, the first direction D1) may be easily connected to each other using a direct-bonding (for example, hybrid copper bonding (HCB)) method, and an occurrence of a defect between the plurality of semiconductor chips 1000 may be minimized.

In addition, the second bonding pad 172 and the second back side bonding pad 192 may be electrically floating dummy pads. In this case, effects of the second bonding pad 172 and the second back side bonding pad 192 on the electrical characteristics of the semiconductor chip 1000 may be minimized.

Thus, a semiconductor package which facilitates interconnection between a plurality of semiconductor chips and has excellent reliability may be provided.

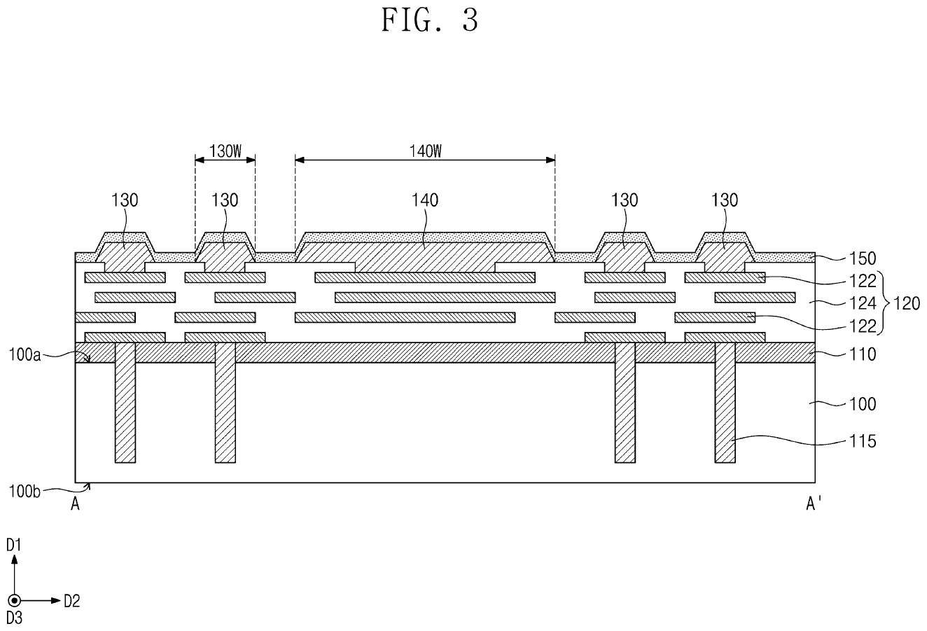

FIGS. 3 to 8 are diagrams, which are cross-sectional views taken along A-A′ of FIG. 1, illustrating a method for manufacturing a semiconductor chip according to some implementations. For conciseness, descriptions overlapping with the above descriptions of the semiconductor chip provided with reference to FIGS. 1 and 2 will not be provided.

Referring to FIG. 3, a semiconductor substrate 100 having a first surface 100a and a second surface 100b opposed to each other may be provided. An integrated circuit layer 110 may be formed on the first surface 100a of the semiconductor substrate 100. A penetration electrode 115 may be formed so as to partially penetrate the semiconductor substrate 100 along the first direction D1. The penetration electrode 115 may be spaced apart from the second surface 100b of the semiconductor substrate 100 along the first direction D1. The penetration electrode 115 may extend into the integrated circuit layer 110 along the first direction D1.

A wiring layer 120 may be formed on the integrated circuit layer 110. The wiring layer 120 may include a plurality of wiring patterns 122 spaced apart from each other in the first direction D1, and a wiring insulating layer 124 disposed on the first surface 100a of the semiconductor substrate 100 and covering the plurality of wiring patterns 122. The penetration electrode 115 may be electrically connected to the wiring layer 120 and the integrated circuit layer 110.

A first pad 130 and a second pad 140 may be formed on the wiring layer 120 and may be horizontally (for example, in the second direction D2) spaced apart from each other. A portion of the first pad 130 may extend into the wiring insulating layer 124 and may be electrically connected to a corresponding wiring pattern 122 among the plurality of wiring patterns 122. The first pad 130 may be electrically connected to the integrated circuit layer 110 through corresponding wiring patterns 122. A portion of the second pad 140 may extend into the wiring insulating layer 124 and may be electrically connected to a corresponding wiring pattern 122 among the plurality of wiring patterns 122. The second pad 140 may be electrically connected to test patterns for testing electrical characteristics of the semiconductor chip 1000 described with reference to FIGS. 1 and 2 through corresponding wiring patterns 122. Each of the first pad 130 and the second pad 140 may have a maximum width along a direction (for example, the second direction D2 or the third direction D3) parallel to the first surface 100a of the semiconductor substrate 100. A maximum width 140W of the second pad 140 may be greater than a maximum width 130W of the first pad 130.

A capping insulating layer 150 may be formed on the wiring layer 120 and conformally cover the first and second pads 130 and 140. For example, the capping insulating layer 150 may be formed through a chemical vapor deposition process and/or an atomic layer deposition process, but implementations are not limited thereto.

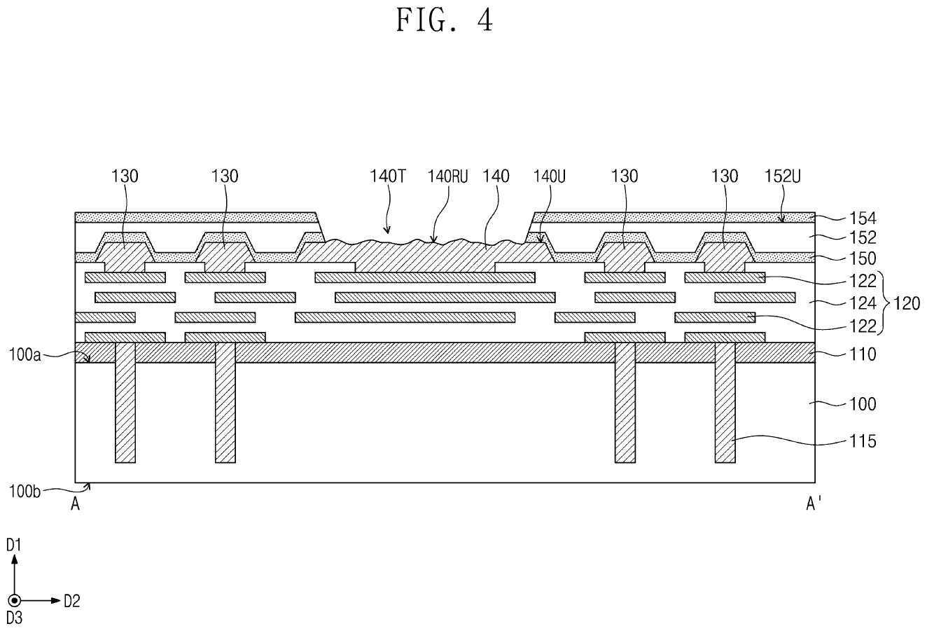

Referring to FIG. 4, a planarized insulating layer 152 may be formed on the capping insulating layer 150. The planarized insulating layer 152 may be formed so as to have a planarized upper surface 152U. A first insulating layer 154 may be formed on the planarized insulating layer 152. For example, the planarized insulating layer 152 and the first insulating layer 154 may be formed through a chemical vapor deposition process and/or an atomic layer deposition process, but implementations are not limited thereto.

An opening 140T may be formed on the second pad 140. The opening 140T may penetrate the first insulating layer 154, the planarized insulating layer 152, and the capping insulating layer 150 along the first direction D1 and expose an upper surface 140U of the second pad 140. Forming the opening 140T may include, for example, forming a mask pattern defining a region in which the opening 140T will be formed on the first insulating layer 154, and etching the first insulating layer 154, the planarized insulating layer 152, and the capping insulating layer 150 by using the mask pattern as an etching mask.

A test process may be performed on the second pad 140 exposed by the opening 140T. The test process may be performed to inspect electrical connection and operation of the semiconductor chip 1000 described with reference to FIGS. 1 and 2. The test process may be performed by bringing a test probe into physical contact with the upper surface 140U of the second pad 140. Accordingly, at least one recessed surface 140RU which is recessed toward an inside of the second pad 140 may be formed through the test process. The upper surface 140U of the second pad 140 may include the at least one recessed surface 140RU.

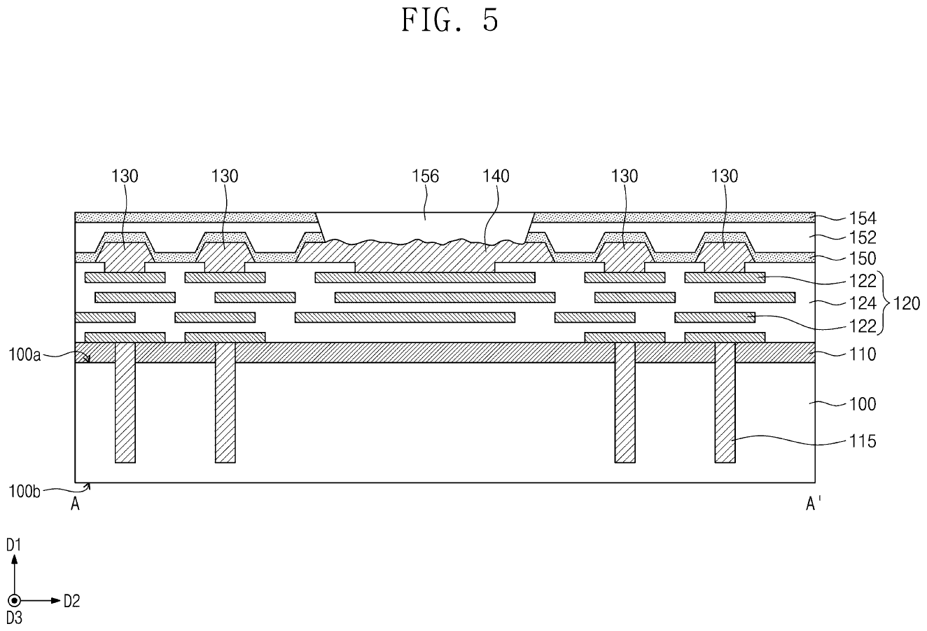

Referring to FIG. 5, a buried insulating pattern 156 may be formed so as to fill the opening 140T. Forming the buried insulating pattern 156 may include, for example, forming a buried insulating layer that fills the opening 140T on the first insulating layer 154, and planarizing the buried insulating layer until an upper surface of the first insulating layer 154 is exposed.

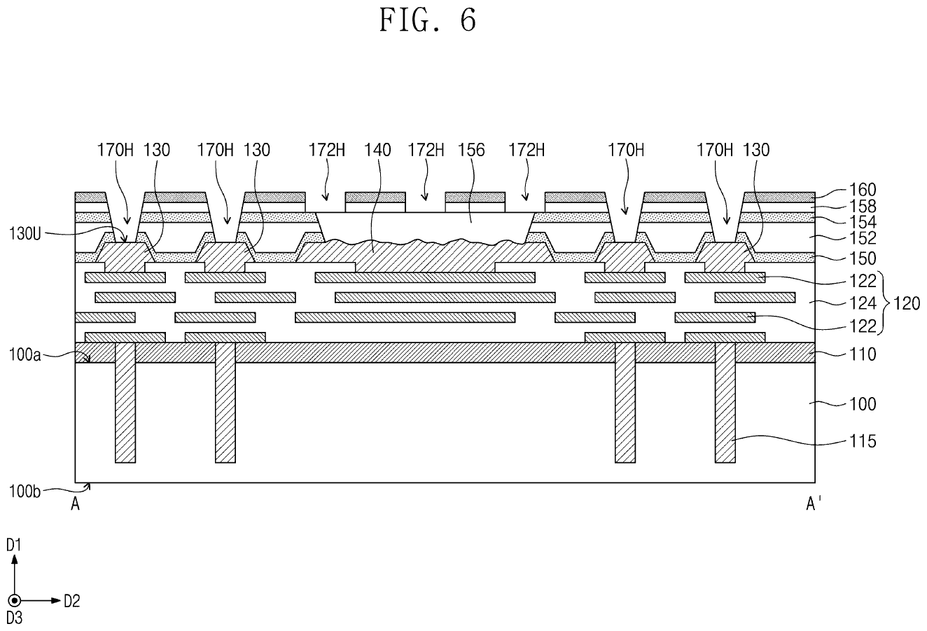

Referring to FIG. 6, a second insulating layer 158 may be formed on the first insulating layer 154 and cover an upper surface of the buried insulating pattern 156. A bonding insulating layer 160 may be formed on the second insulating layer 158. For example, the second insulating layer 158 and the bonding insulating layer 160 may be formed through a chemical vapor deposition process and/or an atomic layer deposition process, but implementations are not limited thereto.

A first hole 170H may be formed on the first pad 130. The first hole 170H may penetrate the bonding insulating layer 160, the first and second insulating layers 154 and 158, the planarized insulating layer 152, and the capping insulating layer 150 along the first direction D1 and expose an upper surface 130U of the first pad 130. A second hole 172H may be formed on the second pad 140 and the buried insulating pattern 156. The second hole 172H may penetrate the bonding insulating layer 160 and the second insulating layer 158 and expose an upper surface of the buried insulating pattern 156. The second hole 172H may vertically overlap the second pad 140 along the first direction D1.

Forming the first hole 170H may include, for example, forming a first mask pattern defining a region in which the first hole 170H will be formed on the bonding insulating layer 160, and etching the bonding insulating layer 160, the first and second insulating layers 154 and 158, the planarized insulating layer 152, and the capping insulating layer 150 by using the first mask pattern as an etching mask. Forming the second hole 172H may include, for example, forming a second mask pattern defining a region in which the second hole 172H will be formed on the bonding insulating layer 160, and etching the bonding insulating layer 160 and the second insulating layer 158 by using the second mask pattern as an etching mask. The first hole 170H and the second hole 172H may be formed through different etching processes, but implementations are not limited thereto. The first hole 170H and the second hole 172H may be simultaneously formed through the same etching process.

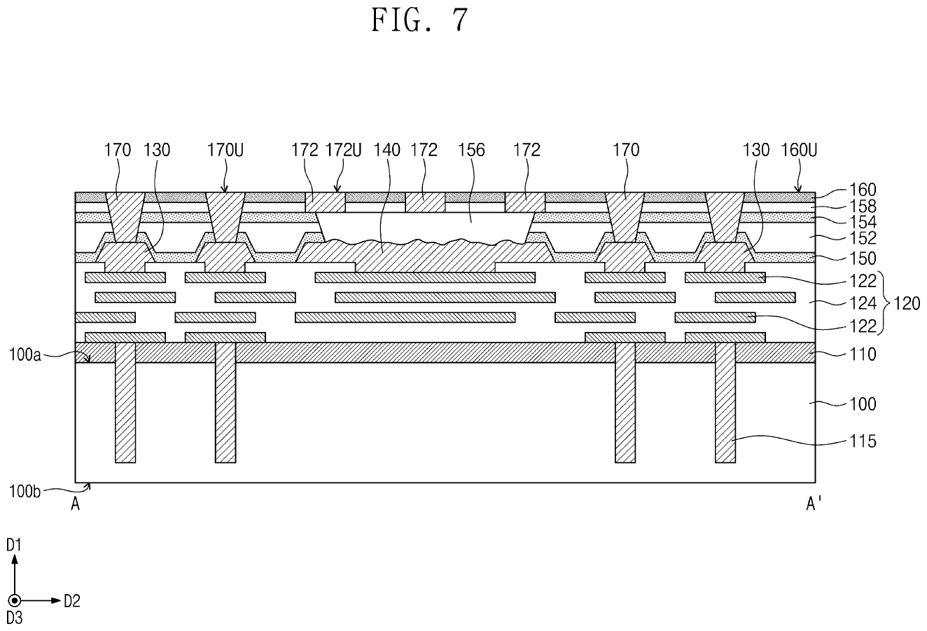

Referring to FIG. 7, a first bonding pad 170 and a second bonding pad 172 may be formed so as to respectively fill the first hole 170H and the second hole 172H. Forming the first bonding pad 170 and the second bonding pad 172 may include, for example, forming a bonding conductive layer that fills the first hole 170H and the second hole 172H on the bonding insulating layer 160, and planarizing the bonding conductive layer until an upper surface 160U of the bonding insulating layer 160 is exposed. For example, a planarization process of planarizing the bonding conductive layer may be performed through a chemical mechanical polishing (CMP) process.

According to some implementations, since the second bonding pad 172 is formed in a region vertically overlapping the second pad 140 having a relatively great width, a pattern density of the first and second bonding pads 170 and 172 may be uniform. Accordingly, occurrence of a defect such as dishing or erosion may be minimized during the planarization process, and as a result, an upper surface 170U of the first bonding pad 170, an upper surface 172U of the second bonding pad 172, and the upper surface 160U of the bonding insulating layer 160 may have uniform distribution of height.

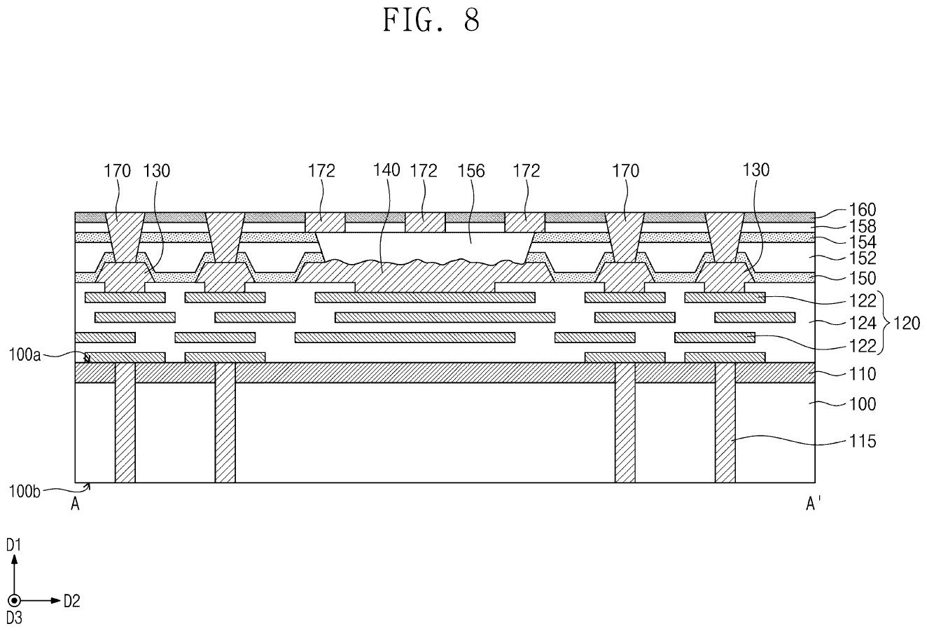

Referring to FIG. 8, a grinding process may be performed on the second surface 100b of the semiconductor substrate 100. The grinding process may be performed so as to expose a lower surface of the penetration electrode 115.

Referring back to FIG. 2, a back side bonding insulating layer 180 may be formed on the second surface 100b of the semiconductor substrate 100. The back side bonding insulating layer 180 may cover the second surface 100b of the semiconductor substrate 100 and the exposed lower surface of the penetration electrode 115. For example, the back side bonding insulating layer 180 may be formed through a chemical vapor deposition process and/or an atomic layer deposition process, but implementations are not limited thereto.

A first back side bonding pad 190 and a second back side bonding pad 192 may be formed in the back side bonding insulating layer 180 and may be horizontally (for example, in the second direction D2) spaced apart from each other. Forming the first back side bonding pad 190 and the second back side bonding pad 192 may include, for example, forming a first back side hole and a second back side hole penetrating the back side bonding insulating layer 180 and horizontally spaced apart from each other, forming a back side bonding conductive layer that fills the first back side hole and the second back side hole on the back side bonding insulating layer 180, and planarizing the back side bonding conductive layer until a lower surface 180L of the back side bonding insulating layer 180 is exposed. The first back side hole may penetrate the back side bonding insulating layer 180 and expose a lower surface of the penetration electrode 115, and the second back side hole may penetrate the back side bonding insulating layer 180 and expose the second surface 100b of the semiconductor substrate 100. For example, a planarization process of planarizing the back side bonding conductive layer may be performed through a chemical mechanical polishing (CMP) process.

According to some implementations, since the second back side bonding pad 192 is formed in a region vertically overlapping the second pad 140 having a relatively great width, a pattern density of the first and second back side bonding pads 190 and 192 may be uniform. Accordingly, occurrence of a defect such as dishing or erosion may be minimized during the planarization process, and as a result, a lower surface 190L of the first back side bonding pad 190, a lower surface 192L of the second back side bonding pad 192, and the lower surface 180L of the back side bonding insulating layer 180 may have uniform distribution of height.

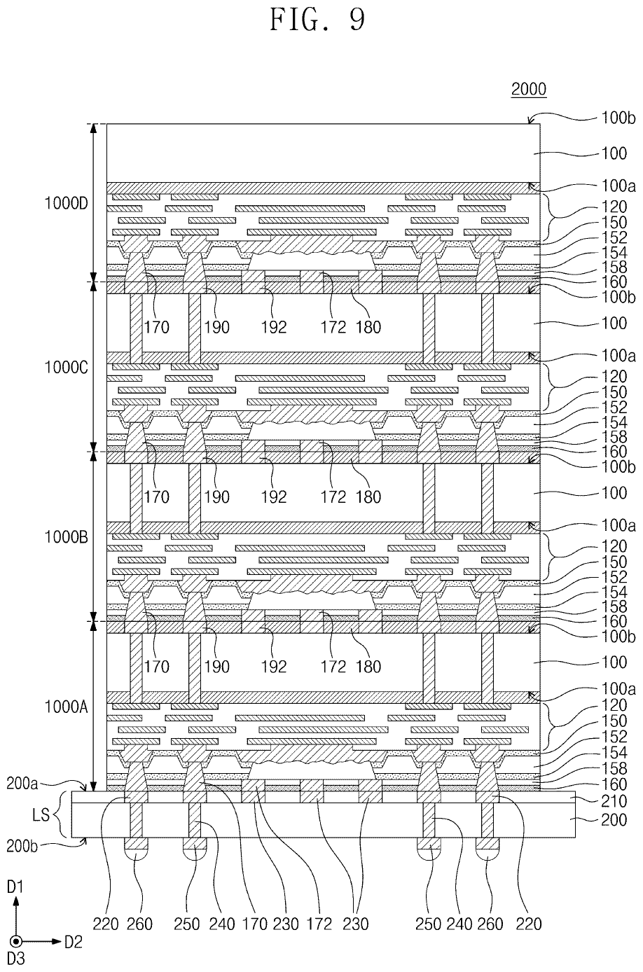

FIG. 9 is a cross-sectional view of a semiconductor package according to some implementations.

Referring to FIG. 9, a semiconductor package 2000 may include a lower structure LS and a plurality of semiconductor chips 1000A, 1000B, 1000C, and 1000D stacked on the lower structure LS in a vertical direction (for example, the first direction D1).

The lower structure LS may have an upper surface 200a and a lower surface 200b opposed to each other, and the plurality of semiconductor chips 1000A, 1000B, 1000C, and 1000D may be stacked on the upper surface 200a of the lower structure LS in the first direction D1. The first direction D1 may be perpendicular to the upper surface 200a of the lower structure LS. FIG. 9 illustrates a structure in which four semiconductor chips 1000A, 1000B, 1000C, and 1000D are stacked on the lower structure LS as an example, but implementations are not limited thereto. The number of the plurality of semiconductor chips 1000A, 1000B, 1000C, and 1000D may be four or more.

The lower structure LS may be a lower semiconductor chip and include a lower substrate 200, a lower insulating layer 210, first lower chip pads 220, dummy chip pads 230, lower penetration electrodes 240, second lower chip pads 250, and lower connection terminals 260.

The lower substrate 200 may be adjacent to the lower surface 200b of the lower structure LS. The lower insulating layer 210 may be disposed on the lower substrate 200 and adjacent to the upper surface 200a of the lower structure LS. The lower substrate 200 may include a semiconductor substrate (for example, a silicon substrate, a germanium substrate, and/or a silicon-germanium substrate) and integrated circuits formed on the semiconductor substrate. The lower insulating layer 210 may include an insulating material, and for example, include silicon oxide, silicon nitride, and/or silicon oxynitride.

The lower penetration electrodes 240 may penetrate the lower substrate 200 along the first direction D1 and may be horizontally (for example, in the second direction D2) spaced apart from each other in the lower substrate 200. The second direction D2 and the third direction D3 may be parallel to the upper surface 200a of the lower structure LS. The lower penetration electrodes 240 may be electrically connected to integrated circuits of the lower substrate 200. The lower penetration electrodes 240 may include metal (for example, copper, tungsten, titanium, tantalum, etc.).

The first lower chip pads 220 and the dummy chip pads 230 may be disposed in the lower insulating layer 210 and may be horizontally (for example, in the second direction D2) spaced apart from each other. The first lower chip pads 220 and the dummy chip pads 230 may be disposed to be adjacent to the upper surface 200a of the lower structure LS. The lower insulating layer 210 may expose upper surfaces of the first lower chip pads 220 and the dummy chip pads 230. The first lower chip pads 220 may be respectively electrically connected to the lower penetration electrodes 240. The dummy chip pads 230 may not be connected to the lower penetration electrodes 240 and may be electrically isolated from the lower penetration electrodes 240. The dummy chip pads 230 may be electrically floating dummy chip pads. The first lower chip pads 220 and the dummy chip pads 230 may include metal (for example, copper).

The second lower chip pads 250 may be disposed on the lower surface 200b of the lower structure LS and may be horizontally (for example, in the second direction D2) spaced apart from each other. The second lower chip pads 250 may be respectively electrically connected to the lower penetration electrodes 240. The second lower chip pads 250 may be electrically connected to the first lower chip pads 220 through the lower penetration electrodes 240. The second lower chip pads 250 may include metal (for example, copper).

The lower connection terminals 260 may be respectively disposed on the second lower chip pads 250. The lower connection terminals 260 may include a conductive material and may have a form of at least one of a solder ball, a bump, or a pillar. The lower structure LS may be electrically connected to external terminals through the lower connection terminals 260.

The plurality of semiconductor chips 1000A, 1000B, 1000C, and 1000D may include a first semiconductor chip 1000A, a second semiconductor chip 1000B, a third semiconductor chip 1000C, and a fourth semiconductor chip 1000D sequentially stacked on the upper surface 200a of the lower structure LS. Each of the first semiconductor chip 1000A, the second semiconductor chip 1000B, and the third semiconductor chip 1000C is substantially the same as the semiconductor chip 1000 described with reference to FIGS. 1 and 2. The fourth semiconductor chip 1000D may be substantially the same as the semiconductor chip 1000 described with reference to FIGS. 1 and 2, but may not include the penetration electrode 115, the first and second back side bonding pads 190 and 192, and the back side bonding insulating layer 180.

The first semiconductor chip 1000A may be disposed so that the first surface 100a of the semiconductor substrate 100 faces the upper surface 200a of the lower structure LS. First bonding pads 170 of the first semiconductor chip 1000A may be respectively directly bonded to the first lower chip pads 220 of the lower structure LS. Second bonding pads 172 of the first semiconductor chip 1000A may be respectively directly bonded to the dummy chip pads 230 of the lower structure LS. A bonding insulating layer 160 of the first semiconductor chip 1000A may be directly bonded to the lower insulating layer 210 of the lower structure LS. That is, the first semiconductor chip 1000A and the lower structure LS may be connected to each other using a direct-bonding (for example, hybrid copper bonding (HCB)) method. The first bonding pads 170 of the first semiconductor chip 1000A may be respectively electrically connected to the first lower chip pads 220 of the lower structure LS. The first semiconductor chip 1000A may be electrically connected to the lower structure LS through the first bonding pads 170 and the first lower chip pads 220.

The second semiconductor chip 1000B may be disposed so that the first surface 100a of the semiconductor substrate 100 faces the second surface 100b of the semiconductor substrate 100 of the first semiconductor chip 1000A. First bonding pads 170 of the second semiconductor chip 1000B may be respectively directly bonded to first back side bonding pads 190 of the first semiconductor chip 1000A. Second bonding pads 172 of the second semiconductor chip 1000B may be respectively directly bonded to second back side bonding pads 192 of the first semiconductor chip 1000A. A bonding insulating layer 160 of the second semiconductor chip 1000B may be directly bonded to a back side bonding insulating layer 180 of the first semiconductor chip 1000A. That is, the first semiconductor chip 1000A and the second semiconductor chip 1000B may be connected to each other using a direct-bonding (for example, hybrid copper bonding (HCB)) method. The first bonding pads 170 of the second semiconductor chip 1000B may be respectively electrically connected to the first back side bonding pads 190 of the first semiconductor chip 1000A. The second semiconductor chip 1000B may be electrically connected to the first semiconductor chip 1000A through the first bonding pads 170 and the first back side bonding pads 190.

The third semiconductor chip 1000C may be disposed so that the first surface 100a of the semiconductor substrate 100 faces the second surface 100b of the semiconductor substrate 100 of the second semiconductor chip 1000B. First bonding pads 170 of the third semiconductor chip 1000C may be respectively directly bonded to first back side bonding pads 190 of the second semiconductor chip 1000B. Second bonding pads 172 of the third semiconductor chip 1000C may be respectively directly bonded to second back side bonding pads 192 of the second semiconductor chip 1000B. A bonding insulating layer 160 of the third semiconductor chip 1000C may be directly bonded to a back side bonding insulating layer 180 of the second semiconductor chip 1000B. That is, the second semiconductor chip 1000B and the third semiconductor chip 1000C may be connected to each other using a direct-bonding (for example, hybrid copper bonding (HCB)) method. The first bonding pads 170 of the third semiconductor chip 1000C may be respectively electrically connected to the first back side bonding pads 190 of the second semiconductor chip 1000B. The third semiconductor chip 1000C may be electrically connected to the second semiconductor chip 1000B through the first bonding pads 170 and the first back side bonding pads 190.

The fourth semiconductor chip 1000D may be disposed so that the first surface 100a of the semiconductor substrate 100 faces the second surface 100b of the semiconductor substrate 100 of the third semiconductor chip 1000C. First bonding pads 170 of the fourth semiconductor chip 1000D may be respectively directly bonded to first back side bonding pads 190 of the third semiconductor chip 1000C. Second bonding pads 172 of the fourth semiconductor chip 1000D may be respectively directly bonded to second back side bonding pads 192 of the third semiconductor chip 1000C. A bonding insulating layer 160 of the fourth semiconductor chip 1000D may be directly bonded to a back side bonding insulating layer 180 of the third semiconductor chip 1000C. That is, the third semiconductor chip 1000C and the fourth semiconductor chip 1000D may be connected to each other using a direct-bonding (for example, hybrid copper bonding (HCB)) method. The first bonding pads 170 of the fourth semiconductor chip 1000D may be respectively electrically connected to the first back side bonding pads 190 of the third semiconductor chip 1000C. The fourth semiconductor chip 1000D may be electrically connected to the third semiconductor chip 1000C through the first bonding pads 170 and the first back side bonding pads 190.

The plurality of semiconductor chips 1000A, 1000B, 1000C, and 1000D may be memory chips. The plurality of semiconductor chips 1000A, 1000B, 1000C, and 1000D may be semiconductor chips which are the same as each other, and for example, may be memory chips which are the same as each other. The lower structure LS may be a memory chip, a logic chip, an application processor (AP) chip, or a system on chip (SOC). The plurality of semiconductor chips 1000A, 1000B, 1000C, and 1000D and the lower structure LS may be electrically connected to each other and may constitute a high bandwidth memory (HBM) chip.

According to some implementations, each of the plurality of semiconductor chips 1000A, 1000B, 1000C, and 1000D may include the second back side bonding pads 192 and the second bonding pads 172 electrically floating, and accordingly, pattern density of the first and second back side bonding pads 190 and 192 and the first and second bonding pads 170 and 172 may be uniform between the plurality of semiconductor chips 1000A, 1000B, 1000C, and 1000D. In this case, distribution of height of a bonding surface (for example, an interface between the first bonding pads 170 and the first back side bonding pads 190, an interface between the second bonding pads 172 and the second back side bonding pads 192, and an interface between the bonding insulating layer 160 and the back side bonding insulating layer 180) between the plurality of semiconductor chips 1000A, 1000B, 1000C, and 1000D may be uniform. Accordingly, occurrence of a defect such as a void at the bonding surface between the plurality of semiconductor chips 1000A, 1000B, 1000C, and 1000D may be minimized, and the plurality of semiconductor chips 1000A, 1000B, 1000C, and 1000D may be easily connected to each other using a direct-bonding (for example, hybrid copper bonding (HCB)) method.

Thus, a semiconductor package which facilitates interconnection between the plurality of semiconductor chips 1000A, 1000B, 1000C, and 1000D and has excellent reliability may be provided.

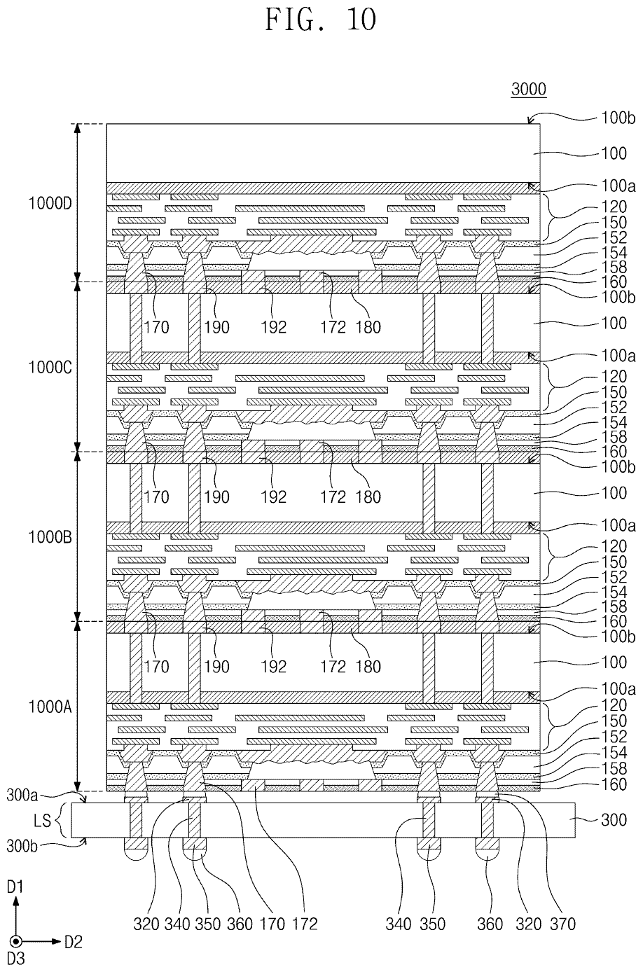

FIG. 10 is a cross-sectional view of a semiconductor package according to some implementations. For conciseness, differences from the semiconductor package described with reference to FIG. 9 will be mainly described.

Referring to FIG. 10, a semiconductor package 3000 may include a lower structure LS and a plurality of semiconductor chips 1000A, 1000B, 1000C, and 1000D stacked on the lower structure LS in a vertical direction (for example, the first direction D1).

The lower structure LS may have an upper surface 300a and a lower surface 300b opposed to each other, and the plurality of semiconductor chips 1000A, 1000B, 1000C, and 1000D may be stacked on the upper surface 300a of the lower structure LS in the first direction D1. The first direction D1 may be perpendicular to the upper surface 300a of the lower structure LS. FIG. 10 illustrates a structure in which four semiconductor chips 1000A, 1000B, 1000C, and 1000D are stacked on the lower structure LS as an example, but implementations are not limited thereto. The number of the plurality of semiconductor chips 1000A, 1000B, 1000C, and 1000D may be four or more.

The lower structure LS may be a lower semiconductor chip and include a lower substrate 300, first lower chip pads 320, lower penetration electrodes 340, second lower chip pads 350, lower connection terminals 360, and upper connection terminals 370.

The lower substrate 300 may include a semiconductor substrate (for example, a silicon substrate, a germanium substrate, and/or a silicon-germanium substrate) and integrated circuits formed on the semiconductor substrate. The upper surface 300a of the lower structure LS may correspond to an upper surface of the lower substrate 300, and the lower surface 300b of the lower structure LS may correspond to a lower surface of the lower substrate 300.

The lower penetration electrodes 340 may penetrate the lower substrate 300 along the first direction D1 and may be horizontally (for example, in the second direction D2) spaced apart from each other in the lower substrate 300. The second direction D2 and the third direction D3 may be parallel to the upper surface 300a of the lower structure LS. The lower penetration electrodes 340 may be electrically connected to integrated circuits of the lower substrate 300. The lower penetration electrodes 340 may include metal (for example, copper, tungsten, titanium, tantalum, etc.).

The first lower chip pads 320 may be disposed on the upper surface 300a (for example, the upper surface of the lower substrate 300) of the lower structure LS and may be horizontally (for example, in the second direction D2) spaced apart from each other. The first lower chip pads 320 may be respectively electrically connected to the lower penetration electrodes 340. The first lower chip pads 320 may include metal (for example, copper).

The second lower chip pads 350 may be disposed on the lower surface 300b (for example, the lower surface of the lower substrate 300) of the lower structure LS and may be horizontally (for example, in the second direction D2) spaced apart from each other. The second lower chip pads 350 may be respectively electrically connected to the lower penetration electrodes 340. The second lower chip pads 350 may be electrically connected to the first lower chip pads 320 through the lower penetration electrodes 340. The second lower chip pads 350 may include metal (for example, copper).

The lower connection terminals 360 may be respectively disposed on the second lower chip pads 350. The lower connection terminals 360 may include a conductive material and may have a form of at least one of a solder ball, a bump, or a pillar. The lower structure LS may be electrically connected to the external terminals through the lower connection terminals 360.

The upper connection terminals 370 may be respectively disposed on the first lower chip pads 320. The upper connection terminals 370 may include a conductive material and may have a form of at least one of a solder ball, a bump, or a pillar.

The plurality of semiconductor chips 1000A, 1000B, 1000C, and 1000D may include a first semiconductor chip 1000A, a second semiconductor chip 1000B, a third semiconductor chip 1000C, and a fourth semiconductor chip 1000D sequentially stacked on the upper surface 300a of the lower structure LS. The first to fourth semiconductor chips 1000A, 1000B, 1000C, and 1000D are substantially the same as the first to fourth semiconductor chips 1000A, 1000B, 1000C, and 1000D described with reference to FIG. 9. The upper connection terminals 370 of the lower structure LS may be respectively connected to the first bonding pads 170 of the first semiconductor chip 1000A. The lower structure LS may be electrically connected to the first semiconductor chip 1000A through the upper connection terminals 370 and the first bonding pads 170.

The semiconductor package 3000 is substantially the same as the semiconductor package 2000 described with reference to FIG. 9 except for the differences described above.

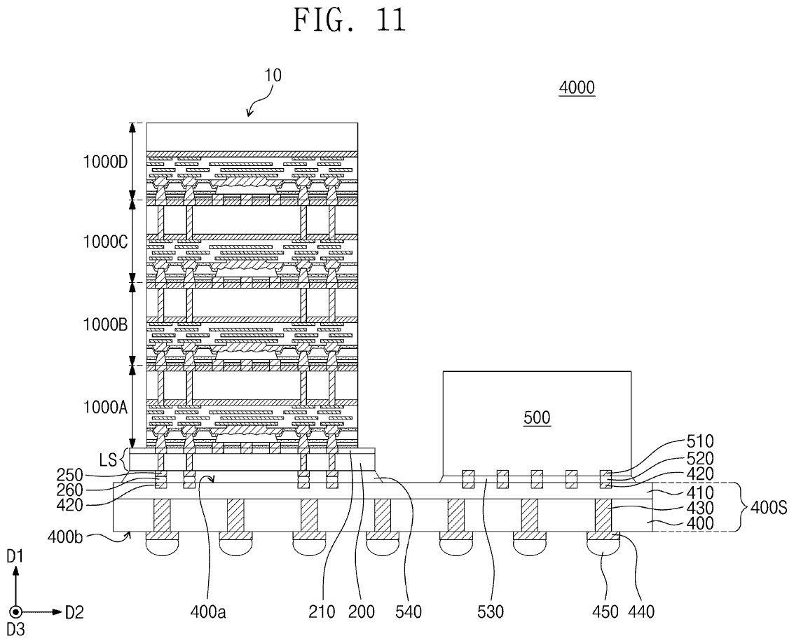

FIG. 11 is a cross-sectional view of a semiconductor package according to some implementations. For conciseness, differences from the semiconductor packages described with reference to FIGS. 9 and 10 will be mainly described.

Referring to FIG. 11, a semiconductor package 4000 may include a first substrate 400S and a unit chip package 10 and an additional semiconductor chip 500 which are mounted on the first substrate 400S.

The first substrate 400S may be an interposer substrate. The first substrate 400S may include a base substrate 400, a plurality of substrate penetration electrodes 430 penetrating the base substrate 400, and a substrate wiring layer 410 on the base substrate 400. The base substrate 400 may be, for example, a silicon substrate. The plurality of substrate penetration electrodes 430 may be horizontally spaced apart from each other in the base substrate 400 and may each penetrate the base substrate 400. The plurality of substrate penetration electrodes 430 may include metal (for example, copper (Cu)). The substrate wiring layer 410 may include metal lines electrically connected to the plurality of substrate penetration electrodes 430.

The first substrate 400S may have an upper surface 400a and a lower surface 400b opposed to each other. The substrate wiring layer 410 may be adjacent to the upper surface 400a of the first substrate 400S, and the base substrate 400 may be adjacent to the lower surface 400b of the first substrate 400S. The lower surface 400b of the first substrate 400S may correspond to a lower surface of the base substrate 400. The plurality of substrate penetration electrodes 430 may each extend from the substrate wiring layer 410 toward the lower surface 400b of the first substrate 400S.

The first substrate 400S may include first conductive pads 420 disposed to be adjacent to the upper surface 400a of the first substrate 400S. The first conductive pads 420 may be spaced apart from each other along a direction (for example, the second direction D2) parallel to the upper surface 400a of the first substrate 400S. The first conductive pads 420 may be electrically connected to the metal lines in the substrate wiring layer 410 and may be electrically connected to the plurality of substrate penetration electrodes 430 through the metal lines. The first conductive pads 420 may include a conductive material (for example, metal).

The first substrate 400S may include second conductive pads 440 disposed on the lower surface 400b of the first substrate 400S. The second conductive pads 440 may be spaced apart from each other along a direction (for example, the second direction D2) parallel to the lower surface 400b of the first substrate 400S, and may be respectively electrically connected to the plurality of substrate penetration electrodes 430. The second conductive pads 440 may include a conductive material (for example, metal).

First connection bumps 450 may be disposed on the lower surface 400b of the first substrate 400S and may be respectively connected to the second conductive pads 440. The first connection bumps 450 may be respectively disposed on the second conductive pads 440. The first connection bumps 450 may include a conductive material and may have a form of at least one of a solder ball, a bump, or a pillar.

The unit chip package 10 and the additional semiconductor chip 500 may be mounted on the upper surface 400a of the first substrate 400S. The unit chip package 10 and the additional semiconductor chip 500 may be spaced apart from each other in a direction (for example, in the second direction D2) parallel to the upper surface 400a of the first substrate 400S. The unit chip package 10 is substantially the same as the semiconductor package 2000 described with reference to FIG. 9. According to some implementations, the unit chip package 10 may be configured in substantially the same manner as the semiconductor package 3000 described with reference to FIG. 10. The lower connection terminals 260 of the lower structure LS of the unit chip package 10 may be connected to corresponding first conductive pads 420 among the first conductive pads 420 of the first substrate 400S. The unit chip package 10 may be electrically connected to the substrate wiring layer 410 of the first substrate 400S through the lower connection terminals 260 and the corresponding first conductive pads 420.

A first underfill layer 540 may be interposed between the lower structure LS of the unit chip package 10 and the first substrate 400S and cover the lower connection terminals 260 of the lower structure LS. The first underfill layer 540 may include an insulating polymer material such as an epoxy resin.

The additional semiconductor chip 500 may be horizontally spaced apart from the unit chip package 10. The additional semiconductor chip 500 may be mounted so as to be horizontally spaced apart from the lower structure LS of the unit chip package 10. The additional semiconductor chip 500 may include additional chip pads 510 disposed on one surface of the additional semiconductor chip 500, and additional bumps 520 respectively connected to the additional chip pads 510. The additional bumps 520 may be connected to corresponding first conductive pads 420 among the first conductive pads 420 of the first substrate 400S. The additional semiconductor chip 500 may be electrically connected to the substrate wiring layer 410 of the first substrate 400S through the additional bumps 520 and the corresponding first conductive pads 420.

A second underfill layer 530 may be interposed between the additional semiconductor chip 500 and the first substrate 400S and cover the additional bumps 520. The second underfill layer 530 may include an insulating polymer material such as an epoxy resin.

The unit chip package 10 and the additional semiconductor chip 500 may be electrically connected to each other through the metal lines in the substrate wiring layer 410 of the first substrate 400S. For example, the unit chip package 10 may include a high bandwidth memory (HBM) chip, and the additional semiconductor chip 500 may be a memory chip, a logic chip, an application processor (AP) chip, or a system on chip (SOC).

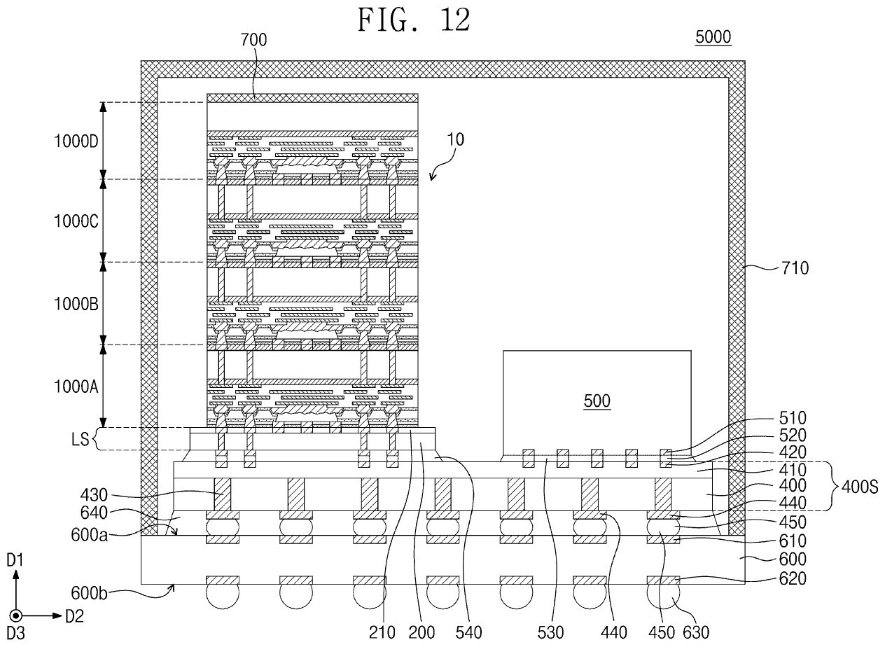

FIG. 12 is a cross-sectional view of a semiconductor package according to some implementations. For conciseness, differences from the semiconductor packages described with reference to FIGS. 9 to 11 will be mainly described.

Referring to FIG. 12, a semiconductor package 5000 may further include a second substrate 600 and a heat dissipation structure 710 on the second substrate 600. Components of the semiconductor packages 2000, 3000, and 4000 described with reference to FIGS. 9 to 11 may be disposed on the second substrate 600 and inside the heat dissipation structure 710.

The second substrate 600 may have an upper surface 600a and a lower surface 600b opposed to each other. The second substrate 600 may include first substrate pads 610 adjacent to the upper surface 600a of the second substrate 600 and second substrate pads 620 adjacent to the lower surface 600b of the second substrate 600. The first substrate pads 610 may be electrically connected to the second substrate pads 620 through internal lines in the second substrate 600. The first and second substrate pads 610 and 620 may include a conductive material.

Second connection bumps 630 may be disposed on the lower surface 600b of the second substrate 600 and respectively connected to the second substrate pads 620. The second connection bumps 630 may include a conductive material and may have a form of at least one of a solder ball, a bump, or a pillar. The second substrate 600 may be, for example, a printed circuit board, a semiconductor chip, or a semiconductor package.

The semiconductor packages 2000, 3000, and 4000 described with reference to FIGS. 9 to 11 may be mounted on the upper surface 600 a of the second substrate 600. The first substrate 400S may be disposed on the upper surface 600a of the second substrate 600. The first connection bumps 450 of the first substrate 400S may be electrically connected to the first substrate pads 610 of the second substrate 600. The first substrate 400S may be electrically connected to the second substrate 600 through the first connection bumps 450 and the first substrate pads 610.

A lower underfill layer 640 may be disposed between the first substrate 400S and the second substrate 600 and cover the first connection bumps 450. The lower underfill layer 640 may include an insulating polymer material such as an epoxy resin.

The heat dissipation structure 710 may be disposed on the upper surface 600a of the second substrate 600 and cover components of the semiconductor packages 2000, 3000, and 4000 described with reference to FIGS. 9 to 11. The heat dissipation structure 710 may include a thermally conductive material. The thermally conductive material may include metal (for example, copper, aluminum, and/or the like) or a carbon-containing material (for example, graphene, graphite, carbon nanotube, and/or the like). For example, the heat dissipation structure 710 may include a single metal layer or a plurality of metal layers which are stacked. For another example, the heat dissipation structure 710 may include a heat sink or a heat pipe. For another example, a water cooling method may be used in the heat dissipation structure 710.

The semiconductor package 5000 may further include a thermally conductive layer 700 interposed between the unit chip package 10 and the heat dissipation structure 710. The thermally conductive layer 700 may include a thermal interface material (TIM). The thermal interface material may include, for example, polymer and thermally conductive particles. The thermally conductive particles may be dispersed in polymer. Heat generated from the unit chip package 10 may be transferred to the heat dissipation structure 710 through the thermally conductive layer 700.

According to some implementations, since a second bonding pad is disposed in a region vertically overlapping a second pad having a relatively great width, a pattern density of first and second bonding pads may be uniform. Accordingly, occurrences of a defect such as dishing or erosion may be minimized during a planarization process for forming the first and second bonding pads, and as a result, upper surfaces of a bonding insulating layer and the first and second bonding pads may have a uniform distribution of height. In addition, since a second back side bonding pad is disposed in a region vertically overlapping the second pad having a relatively great width, a pattern density of first and second back side bonding pads may be uniform. Accordingly, occurrences of a defect such as dishing or erosion may be minimized during a planarization process for forming the first and second back side bonding pads, and as a result, lower surfaces of a back side bonding insulating layer and the first and second back side bonding pads may have a uniform distribution of height. Accordingly, a plurality of semiconductor chips stacked in a vertical direction may be easily connected to each other using a direct-bonding (for example, hybrid copper bonding (HCB)) method, and occurrence of a defect between the plurality of semiconductor chips may be minimized.

Thus, a semiconductor chip having a structure which facilitates interconnection between the plurality of semiconductor chips may be provided, and a semiconductor package which facilitates interconnection between the plurality of semiconductor chips and has excellent reliability may be provided.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The above descriptions of implementations provide descriptive examples. Therefore, implementations are not limited to the above, and it would be obvious that those skilled in the art could make various modifications and changes by combining the above implementations.

What is claimed is:

1. A semiconductor package comprising a semiconductor chip, the semiconductor chip including:
a semiconductor substrate having a first surface and a second surface opposite to the first surface,
an integrated circuit layer on the first surface of the semiconductor substrate,
a wiring layer on the integrated circuit layer,
a first pad and a second pad horizontally spaced apart from each other on the wiring layer and electrically connected to the wiring layer,
a first bonding pad on the first pad, the first bonding pad being electrically connected to the first pad,
a buried insulating pattern on the second pad, and
a second bonding pad on the buried insulating pattern, the second bonding pad being electrically isolated from the second pad by the buried insulating pattern.

2. The semiconductor package of claim 1, wherein each of the first pad and the second pad has a width along a first direction parallel to the first surface, and
wherein a maximum width of the second pad is greater than a maximum width of the first pad.

3. The semiconductor package of claim 1, wherein an upper surface of the second pad comprises at least one recessed surface recessed toward an inside of the second pad.

4. The semiconductor package of claim 1, wherein the semiconductor chip comprises a planarized insulating layer on the wiring layer and covering the first pad and the second pad, and
wherein the buried insulating pattern extends through the planarized insulating layer and is on the second pad.

5. The semiconductor package of claim 4, wherein the semiconductor chip comprises a bonding insulating layer on the planarized insulating layer,
wherein the first bonding pad extends through the bonding insulating layer and the planarized insulating layer and is connected to the first pad, and
wherein the second bonding pad extends through the bonding insulating layer and is on the buried insulating pattern.

6. The semiconductor package of claim 5, wherein the bonding insulating layer exposes upper surfaces of the first bonding pad and the second bonding pad.

7. The semiconductor package of claim 1, wherein each of the first bonding pad and the second bonding pad has a vertical length along a direction perpendicular to the first surface, and
wherein a vertical length of the first bonding pad is greater than a vertical length of the second bonding pad.

8. The semiconductor package of claim 7, wherein the first bonding pad and the second bonding pad comprise a same metal.

9. The semiconductor package of claim 1, wherein the semiconductor chip comprises:
a first back side bonding pad and a second back side bonding pad being on the second surface of the semiconductor substrate and horizontally spaced apart from each other; and
a penetration electrode extending through the semiconductor substrate and electrically connected to the first back side bonding pad,
wherein the first back side bonding pad is electrically connected to the wiring layer through the penetration electrode, and
wherein the second back side bonding pad is electrically isolated from the penetration electrode and the wiring layer.

10. The semiconductor package of claim 9, wherein the semiconductor chip comprises:
a back side bonding insulating layer being on the second surface of the semiconductor substrate and covering side surfaces of the first back side bonding pad and the second back side bonding pad, and
wherein the back side bonding insulating layer exposes lower surfaces of the first back side bonding pad and the second back side bonding pad.

11. The semiconductor package of claim 9, wherein the first and second bonding pads and the first and second back side bonding pads comprise a same metal.

12. A semiconductor package comprising:
a first semiconductor chip; and
a second semiconductor chip on the first semiconductor chip,
each of the first and second semiconductor chips including:
a semiconductor substrate having a first surface and a second surface opposite to the first surface,
a wiring layer on the first surface of the semiconductor substrate,
a first pad and a second pad horizontally spaced apart from each other on the wiring layer and electrically connected to the wiring layer,
a first bonding pad on the first pad, the first bonding pad being electrically connected to the first pad,
a second bonding pad on the second pad, the second bonding pad being electrically isolated from the second pad,
a first back side bonding pad and a second back side bonding pad on the second surface of the semiconductor substrate and horizontally spaced apart from each other, and
a penetration electrode extending through the semiconductor substrate and electrically connected to the first back side bonding pad,
wherein the second back side bonding pad is electrically isolated from the penetration electrode,
wherein the first back side bonding pad of the first semiconductor chip is directly bonded to the first bonding pad of the second semiconductor chip, and
wherein the second back side bonding pad of the first semiconductor chip is directly bonded to the second bonding pad of the second semiconductor chip.

13. The semiconductor package of claim 12, wherein each of the first pad and the second pad has a width along a first direction parallel to the first surface of the semiconductor substrate, and
wherein a maximum width of the second pad is greater than a maximum width of the first pad.

14. The semiconductor package of claim 12, wherein an upper surface of the second pad comprises at least one recessed surface recessed toward an inside of the second pad.

15. The semiconductor package of claim 12, wherein each of the first and second semiconductor chips comprises:
a planarized insulating layer on the wiring layer and covering the first pad and the second pad; and
a buried insulating pattern extending through the planarized insulating layer and on an upper surface of the second pad,
wherein the first bonding pad extends through the planarized insulating layer and is connected to the first pad, and
wherein the second bonding pad is on the buried insulating pattern and is electrically isolated from the second pad by the buried insulating pattern.

16. The semiconductor package of claim 12, wherein each of the first and second semiconductor chips comprises:
a bonding insulating layer covering side surfaces of the first bonding pad and the second bonding pad and exposing upper surfaces of the first bonding pad and the second bonding pad; and
a back side bonding insulating layer covering side surfaces of the first back side bonding pad and the second back side bonding pad and exposing lower surfaces of the first back side bonding pad and the second back side bonding pad,
wherein the back side bonding insulating layer of the first semiconductor chip is directly bonded to the bonding insulating layer of the second semiconductor chip.

17. The semiconductor package of claim 12, wherein the first and second bonding pads and the first and second back side bonding pads comprise the same metal.

18. The semiconductor package of claim 12, wherein each of the first bonding pad and the second bonding pad has a vertical length along a direction perpendicular to the first surface, and
wherein a vertical length of the first bonding pad is greater than a vertical length of the second bonding pad.

19. A semiconductor package comprising
a semiconductor chip,
the semiconductor chip including:
a semiconductor substrate having a first surface and a second surface opposite to the first surface,
a wiring layer on the first surface of the semiconductor substrate,
a first pad and a second pad horizontally spaced apart from each other on the wiring layer, the first pad and the second pad being electrically connected to the wiring layer,
a planarized insulating layer on the wiring layer, the planarized insulating layer covering the first pad and the second pad,
a bonding insulating layer on the planarized insulating layer,
a first bonding pad extending through the bonding insulating layer and the planarized insulating layer, the first bonding pad being connected to the first pad, and
a second bonding pad extending through the bonding insulating layer, and
wherein the second bonding pad is vertically spaced apart from the second pad and is electrically isolated from the second pad.

20. The semiconductor package of claim 19, wherein each of the first pad and the second pad has a width along a first direction parallel to the first surface,
a maximum width of the second pad is greater than a maximum width of the first pad, and
an upper surface of the second pad comprises at least one recessed surface recessed toward an inside of the second pad.
